(19) United States
(12) Patent Application Publication
(10) Pub. No.: US 2016/0121531 A1
(43) Pub. Date: May 5, 2016

(54) HOUSING, METHOD FOR MAKING THE SAME, ELECTRONIC DEVICE, AND AUTOMOTIVE INTERIOR COMPONENT

(71) Applicant: HON HAI PRECISION INDUSTRY CO., LTD., New Taipei (TW)

(72) Inventors: HUNG-CHUN MA, New Taipei (TW); FENG-YUEN DAI, New Taipei (TW); CHIH-JUNG CHANG, New Taipei (TW); YU-LIN LIAO, New Taipei (TW); HAN-LUNG LEE, New Taipei (TW); JIH-CHEN LIU, New Taipei (TW)

(21) Appl. No.: 14/585,855

(22) Filed: Dec. 30, 2014

(30) Foreign Application Priority Data
Nov. 5, 2014 (TW) 103138315

(51) Int. Cl. B29C 45/26; H05K 5/03; B29C 45/17; A45C 11/00; B29C 45/14; B29C 45/34; H05K 5/02; B60R 11/00

(52) U.S. Cl. CPC B29C 45/263; H05K 5/0217; H05K 5/03; H05K 5/0252; B60R 11/00; A45C 11/00; B29C 45/14; B29C 45/34; B29C 45/1701; B60R 2011/005; A45C 2011/001; A45C 2011/003; A45C 2011/002; B29L 2031/3425

(57) ABSTRACT

A housing includes a substrate and a protective layer. One surface of the substrate defines a groove. An interior wall of the groove defines at least one through hole passing through the substrate. The protective layer is formed on an interior wall of the groove and the surface of the substrate beside the groove. The protective layer is fully attached to the internal wall of the groove.

### FIELD

The subject matter herein generally relates to housings, and more particularly, to a housing, a method for making the housing, an electronic device using the housing, and an automotive interior component using the housing.

### BACKGROUND

Housings applied in electronic devices (such as mobile phones, tablet computers, and multimedia players) may include a substrate and a resin layer formed on the substrate. Typically, the substrate may include at least one recess for receiving a logo.

### BRIEF DESCRIPTION OF THE DRAWINGS

Implementations of the present technology will now be described, by way of example only, with reference to the attached figures.

FIG. 1 is an isometric view of an embodiment of an electronic device having a housing.

FIG. 2 is an isometric view of an embodiment of an automotive interior component having a housing.

FIG. 3 is a cross-sectional view taken along line II-II of FIGS. 1-2.

FIG. 4 is a flowchart of an embodiment of a method for making a housing.

FIG. 5 is a cross-sectional view of an embodiment of a mold core used in the method of FIG. 4.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

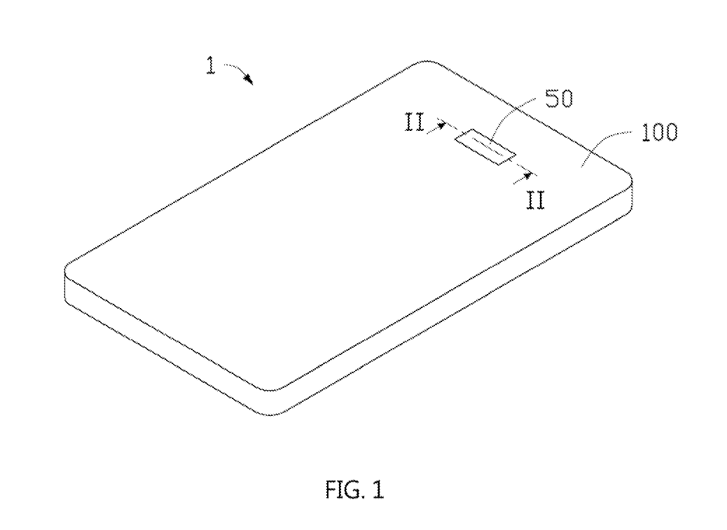

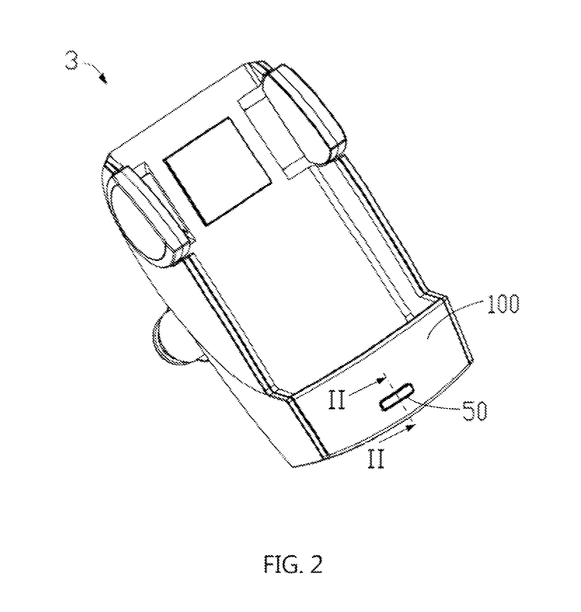

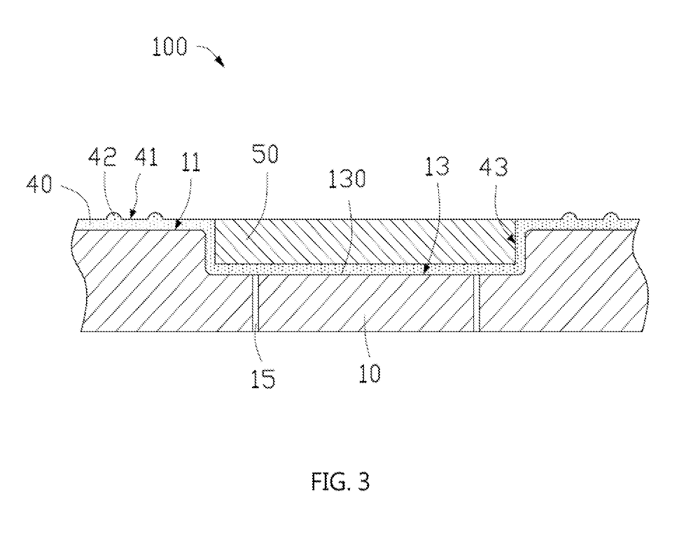

FIGS. 1-3 illustrate an embodiment of a housing 100 applied in an electronic device 1 or an automotive interior component 3. The electronic device 1 can be a cell phone, a tablet computer, or a media player. The automotive interior component 3 can be a digital audio player dock or a cell phone holder.

The housing 100 includes a substrate 10. The substrate 10 can be made of a metal or an alloy. The metal is selected from a group consisting of copper (Cu), aluminum (Al), magnesium (Mg), titanium (Ti), or any combination thereof. One surface 11 of the substrate 10 defines a groove 13. An interior wall 130 of the groove 13 defines at least one through hole 15 passing through the substrate 10. A width of the through hole 15 can be less than 100 gm. In at least one embodiment, the through hole 15 is defined in a bottom of the groove 13 along a direction substantially perpendicular to the bottom of the groove 13.

A protective layer 40 is formed on the interior wall 130 of the groove 13 and the surface 11 of the substrate 10 beside the groove 13, and is fully attached to the internal wall of the groove 13. The protective layer 40 can have a thickness of about 10 μm to about 100 μm. The protective layer 40 can be made of a resin material selected from a group consisting of a thermoplastic polymer, a thermosetting polymer, and an UV curable polymer.

In at least one embodiment, a recess 43 aligned with the groove 13 is formed by a portion of the protective layer 40 located in the groove 13. Furthermore, a desired three-dimensional (3D) relief pattern 42 is formed on a surface 41 of the protective layer 40 away from the substrate 10, and is located at positions beside the recess 43. The pattern 42 includes a plurality of projection-shaped structures or concave structures. An inlay 50 is fixedly received in the recess 43. The inlay 50 can be formed into a pattern, such as a logo.

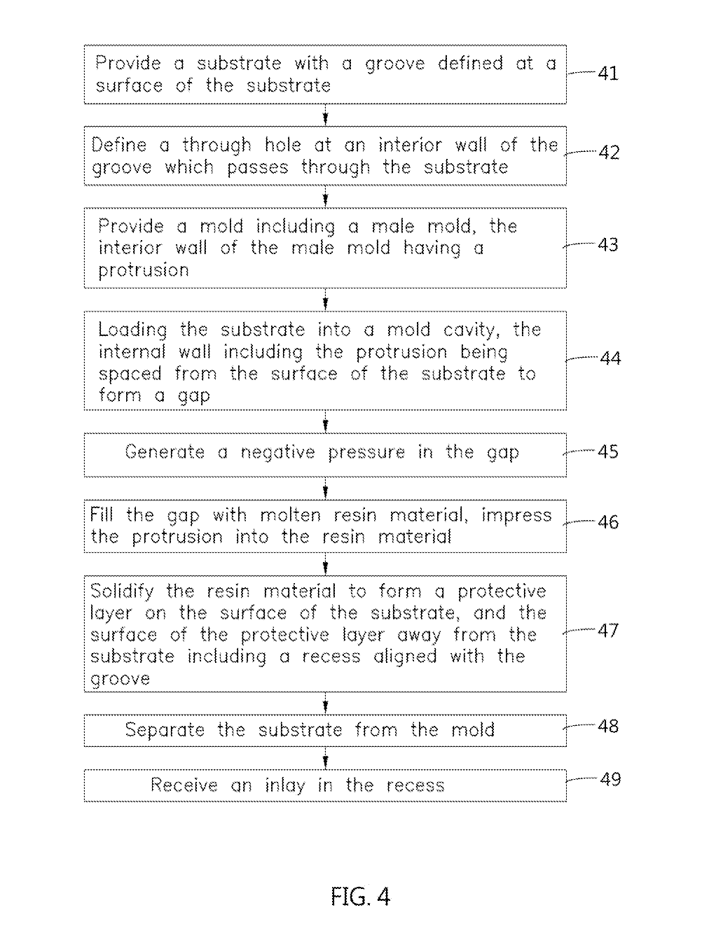

Referring to FIG. 4, a flowchart is presented in accordance with an example embodiment which is being thus illustrated. The example method for making the housing 100 is provided by way of example, as there are a variety of ways to carry out the method. The method described below can be carried out using the configurations illustrated in FIGS. 1-3, for example, and various elements of these figures are referenced in explaining the example method. Each block shown in FIG. 4 represents one or more processes, methods or subroutines, carried out in the exemplary method. Additionally, the illustrated order of blocks is by example only and the order of the blocks can change according to the present disclosure. The exemplary method can begin at block 41.

At block 41, the substrate 10 is provided. The surface 11 of the substrate 10 defines a groove 13.

At block 42, at least one through hole 15 is defined at the interior wall 130 of the groove 13 which passes through the substrate 10. In at least one embodiment, the surface 11 of the substrate 10 is engraved by a laser beam to form the through hole 15.

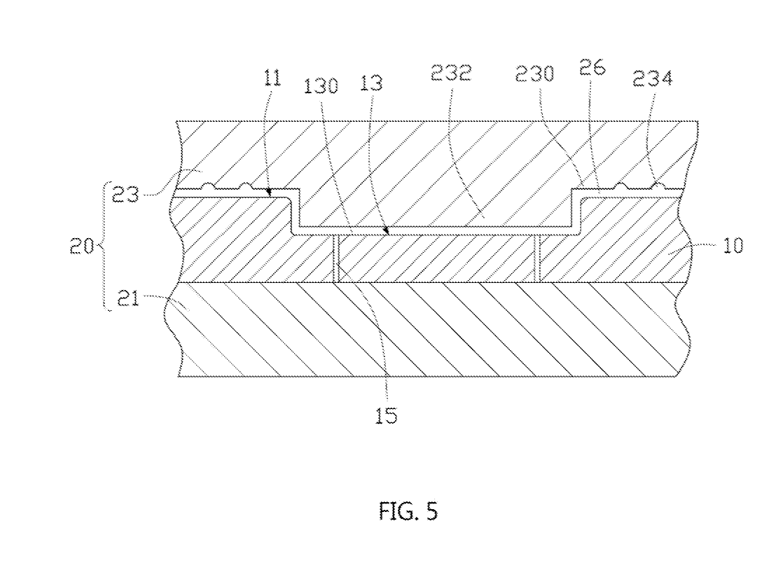

At block 43, a mold 20 (shown in FIG. 5) including a female mold core 21 and a male mold core 23 is provided. The female mold core 21 and the male mold core 23 cooperatively form a mold cavity (not shown). A molding surface 230 of the male mold core 23 includes a protrusion 232. The molding surface 230 further includes a 3D relief pattern 234 formed on the molding surface 230 and located at positions beside the protrusion 232. The pattern 234 includes a plurality of projection-shaped structures or concave structures.

At block 44, the substrate 10 is loaded into the mold cavity, with the groove 13 of the substrate 10 facing the protrusion 232 of the male mold core 23. The molding surface 230 is spaced from the surface 11 of the substrate 10 to form a gap 26. The gap 26 communicates with the through hole 15.

At block 45, a vacuum generator (not shown) is provided and coupled with the through hole 15 through a suction pipe (not shown). The vacuum generator is configured to evacuate the mold cavity via the through hole 15, thereby generating a negative pressure in the gap 26. In at least one embodiment, the female mold core 21 further defines at least one drain hole (not shown) each aligned with one corresponding through hole 15 of the substrate 10. The suction pipe is coupled with the drain hole of the female mold core 21, thereby evacuating the mold cavity via the drain hole and the through hole 15.

At block 46, the gap 26 is filled with a molten resin material, and the protrusion 232 formed at the male mold core 23 is depressed into the resin material. Since the gap 26 is in a negative pressure, the resin material is capable of being fully attached to the interior wall 130 of the groove 13 and the surface 11 of the substrate 10 beside the groove 13. Furthermore, the viscosity of the resin material should be high enough to prevent the resin material in the gap 26 from entering the through hole 15.

At block 47, the resin material is solidified to form a protective layer 40 on the surface 11 of the substrate 10, and the surface 41 of the protective layer 40 away from the substrate 10 includes the recess 43 corresponding to the protrusion 232 and aligned with the groove 13. The protective layer 40 is fully attached to the internal wall of the groove 13 and the surface 11 of the substrate 10 beside the groove 13, and no bubbles are generated at corners of the groove 13.

At block 48, the substrate 10 with the protective layer 40 is separated from the mold 20. In at least one embodiment, the bonding force between the resin material and the substrate 10 is greater than the bonding force between the resin material and the mold 20. As such, the substrate 10 with the protective layer 40 can be easily separated from the mold 20.

At block 49, the inlay 50 is fixed in the recess 43. In at least one embodiment, this can be carried out by coating the interior wall of the recess 43 with adhesive, followed by fixing the inlay 50 to the recess 43 via the adhesive. Then, the housing 100 including the inlay 50 is formed.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

1. A housing comprising:
a substrate, one surface of the substrate defining a groove, an interior wall of the groove defining at least one through hole passing through the substrate; and
a protective layer formed on an interior wall of the groove and the surface of the substrate beside the groove, and fully attached to the internal wall of the groove.

2. The housing of claim 1, wherein a width of the through hole is less than 100 μm.

3. The housing of claim 1, wherein the through hole is defined in a bottom of the groove along a direction substantially perpendicular to the bottom of the groove.

4. The housing of claim 1, wherein the protective layer has a thickness of about 10 μm to about 100 μm.

5. The housing of claim 1, wherein the protective layer is made of a resin material selected from a group consisting of a thermoplastic polymer, a thermosetting polymer, and an UV curable polymer.

6. The housing of claim 1, wherein a recess aligned with the groove is formed at by a portion of the protective layer located in the groove, and an inlay is fixedly received in the recess.

7. The housing of claim 6, wherein a three-dimensional relief pattern is formed on a surface of the protective layer away from the substrate, and is located at positions beside the recess.

8. The housing of claim 7, wherein the pattern comprises a plurality of projection-shaped structures or concave structures.

9. The housing of claim 6, wherein the inlay is formed into a pattern.

10. An electronic device comprising:
a housing comprising:
a substrate, one surface of the substrate defining a groove, an interior wall of the groove defining at least one through hole passing through the substrate; and
a protective layer formed on an interior wall of the groove and the surface of the substrate beside the groove, and fully attached to the internal wall of the groove.

11. The electronic device of claim 10, wherein a width of the through hole is less than 100 μm.

12. The electronic device of claim 10, wherein the protective layer has a thickness of about 10 μm to about 100 μm.

13. The electronic device of claim 10, wherein a recess aligned with the groove is formed by a portion of the protective layer located in the groove, and an inlay is fixedly received in the recess.

14. The electronic device of claim 13, wherein a three-dimensional relief pattern is formed on a surface of the protective layer away from the substrate, and is located at positions beside the recess.

15. An automotive interior component comprising:
a housing comprising:
a substrate, one surface of the substrate defining a groove, an interior wall of the groove defining at least one through hole passing through the substrate; and
a protective layer formed on an interior wall of the groove and the surface of the substrate beside the groove, and fully attached to the internal wall of the groove.

16. The automotive interior component of claim 15, wherein a recess aligned with the groove is formed by a portion of the protective layer located in the groove, and an inlay is fixedly received in the recess.

17. A method for making a housing comprising:
providing a substrate, a surface of the substrate defining a groove;
defining at least one through hole in an interior wall of the groove which passes through the substrate;
providing a mold including a female mold core and a male mold core, the female mold core and the male mold core cooperatively forming a mold cavity;
loading the substrate into the mold cavity, to cause a molding surface of the male mold core to be spaced from the surface of the substrate to form a gap therebetween, the gap communicating with the through hole;
evacuating the mold cavity via the through hole, thereby generating a negative pressure in the gap;
filling the gap with a molten resin material;
solidifying the resin material to form a protective layer on the surface of the substrate, the protective layer fully attached to an internal wall of the groove and the surface of the substrate beside the groove; and
separating the substrate with the protective layer from the mold.

18. The method of claim 17, wherein the molding surface of the male mold core comprises a protrusion; the groove of the substrate faces the protrusion when the substrate is loaded into the mold cavity; the protrusion is depressed into the resin material when the gap is filled with the resin material, to cause a surface of the protective layer away from the substrate to comprises a recess corresponding to the protrusion and aligned with the groove.

19. The method of claim 18, further comprising:
fixing an inlay in the recess.

20. The method of claim 18, wherein step of fixing an inlay in the recess further comprising:
coating an interior wall of the recess with adhesive; and
fixing the inlay to the recess via the adhesive.
